(19) United States
(12) Patent Application Publication
(10) Pub. No.: US 2009/0061615 A1
(43) Pub. Date: Mar. 5, 2009

(54) METHOD FOR FORMING CONTACT IN SEMICONDUCTOR DEVICE

(75) Inventors: Sang-Hoon CHO, Ichon-shi (KR); Sang-Oh LEE, Ichon-shi (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Ichon-shi (KR)

(21) Appl. No.: 11/964,282

(22) Filed: Dec. 26, 2007

(30) Foreign Application Priority Data
Aug. 31, 2007 (KR) 10-2007-0088146

(51) Int. Cl. H01L 21/4763

(52) U.S. Cl. 438/618; 257/E21.495

(57) ABSTRACT

A method for fabricating a semiconductor device includes providing a substrate, forming an insulation layer over the substrate, forming a photoresist pattern for a contact hole over the insulation layer, wherein the photoresist pattern includes an opening having a critical dimension (CD) greater than a desired contact CD, forming a contact hole by selectively etching the insulation layer using the photoresist pattern, and forming a spacer on a sidewall of the contact hole until a CD of the contact hole whose sidewall is covered by the spacer is reduced to a desired contact CD.

### CROSS-REFERENCE TO RELATED APPLICATIONS

The present invention claims priority of Korean patent application number 2007-0088146, filed on Aug. 31, 2007, which is incorporated by reference in its entirety.

### BACKGROUND OF THE INVENTION

The present invention relates to a method for forming a semiconductor device and, more particularly, to a method for forming a contact in a semiconductor device.

Semiconductor devices such as a dynamic random access memory (DRAM) device include multi-layered metal lines. Thus, a process for forming a contact is required to connect upper metal lines and lower metal lines.

Recently, as the semiconductor devices are highly integrated, an aspect ratio of the contact is increased. Thus, various problems occur during the process for forming the contact. These problems will be described in more detail referring to FIGS. 1A to 1C.

Referring to FIG. 1A, a bit line 11 including a bit line conductive layer 11A and a bit line hard mask layer 11B is formed over a substrate (not shown) including a certain lower structure.

Subsequently, a first insulation layer 12 is formed over the resultant structure including the bit line 11. An etch stop layer 13 and a second insulation layer 14 are formed over the first insulation layer 12. The second insulation layer 14 is formed to have a thickness enough to cover a capacitor (not shown) formed in a cell region in a semiconductor memory device.

After forming a hard mask layer 15 for a contact hole process over the second insulation layer 14, a photoresist pattern 17 having an opening to expose a targeted contact hole region is formed over the hard mask layer 15. An anti-reflection layer 16 can be interposed below the photoresist pattern 17 to prevent reflection during a photo-exposure process.

Referring to FIG. 1B, the hard mask layer 15 is etched using the photoresist pattern 17 as an etch mask to form a hard mask pattern 15A. During the etch process, the photoresist pattern 17 can be lost in a certain degree.

Referring to FIG. 1C, the second insulation layer 14, the etch stop layer 13, the first insulation layer 12 and the bit line hard mask layer 11B are etched, using the hard mask pattern 15A as a etch barrier, to form a contact hole 18 exposing the bit line conductive layer 11A. Then, the hard mask pattern 15A is removed. Subsequently, a contact (not shown) is formed by filling a conductive layer in the contact hole 18 and an upper metal line (now shown) is formed over the second insulation layer 14 to connect the contact.

However, as a design rule decreases, a develop inspection critical dimension (DICD) of the photoresist pattern 17 sharply decreases, e.g., under approximately 40 nm, which causes the following problems during the process for forming the contact hole.

First, a thickness of the photoresist pattern 17 is also substantially reduced as the DICD decreases, and thus it is difficult to etch even the hard mask layer 15 using the photoresist pattern 17.

While the DICD of the photoresist pattern 17 decreases, a height of the capacitor in the cell region is increasing to secure desired capacitance. Accordingly, a height of the second insulation layer 14 also increases to cover the capacitor. This means that the contact hole 18 has a top portion with a decreased CD while having an increased depth. That is, the aspect ratio of the contact hole 18 is increased. However, in case of using a typical dry-etch apparatus, the CD of the contact hole 18 decreases as it goes down from a top portion to a bottom portion. Thus, a contact open failure may occur for forming the contact hole 18 due to the increased aspect ratio of the contact hole 18 (refer to a dotted line in FIG. 1C).

To overcome the above problems, it can be considered to increase the DICD of the photoresist pattern 17, thereby increasing the thickness of the photoresist pattern 17 and securing a contact open margin. However, the DICD increase of the photoresist pattern 17 and the subsequent CD increase of a top portion of the contact hole 18 may cause a bridge problem between the contact and an adjacent metal line. This problem occurs more frequently in a word line strapping structure for connecting the word line directly with metal lines in order to decrease a sub-word line area in a peripheral circuit region because the word lines and the metal lines have the same pitch.

### SUMMARY OF THE INVENTION

The present invention is directed to providing a method for forming a contact in a semiconductor device.

In accordance with an aspect of the present invention, there is provided a method for fabricating a semiconductor device. The method includes providing a substrate, forming an insulation layer over the substrate, forming a photoresist pattern for a contact hole over the insulation layer, wherein the photoresist pattern includes an opening having a CD greater than a desired contact CD, forming a contact hole by selectively etching the insulation layer using the photoresist pattern, and forming a spacer on a sidewall of the contact hole until a CD of the contact hole whose sidewall is covered by the spacer is reduced to a desired contact CD.

### BRIEF DESCRIPTION OF THE DRAWINGS

FIGS. 1A to 1C are cross-sectional views of a conventional method for forming a contact in a semiconductor device.

FIGS. 2A to 2D are cross-sectional views of a method for forming a contact in a semiconductor device in accordance with an embodiment of the present invention.

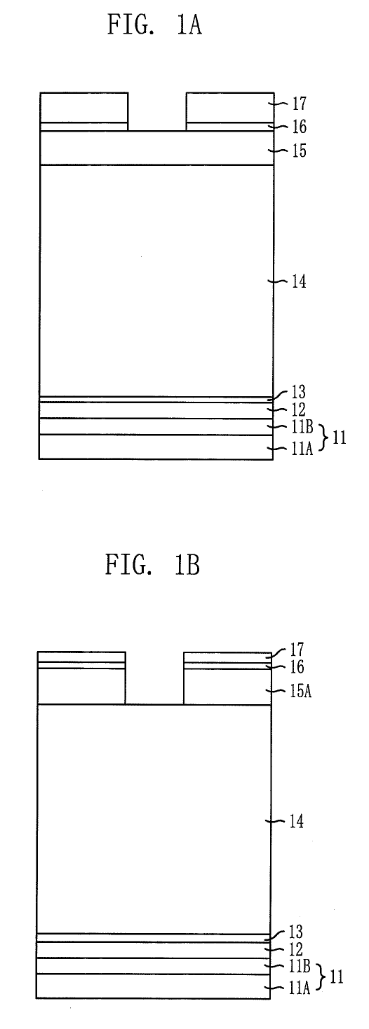

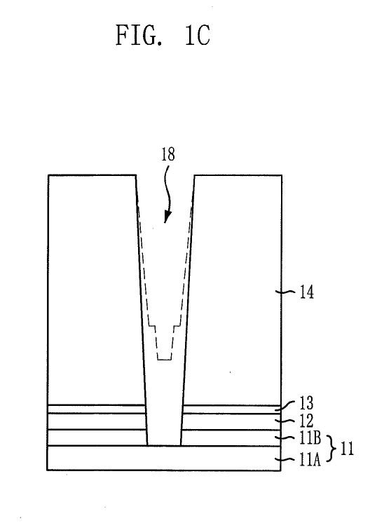

### DESCRIPTION OF SPECIFIC EMBODIMENTS

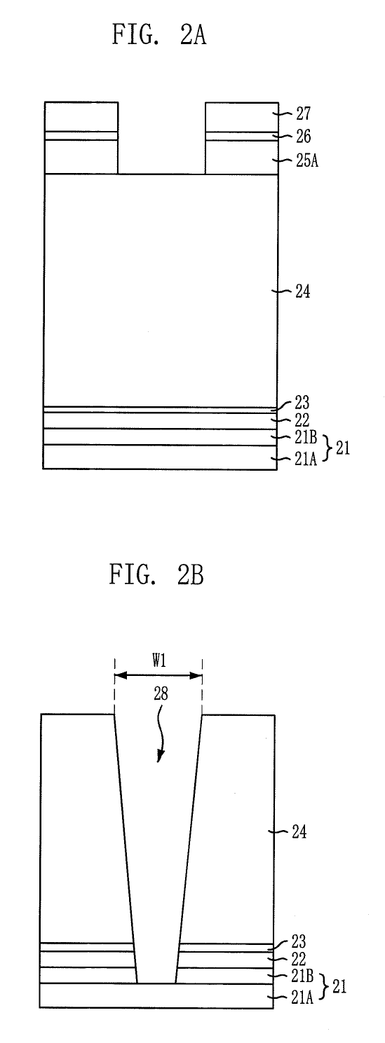

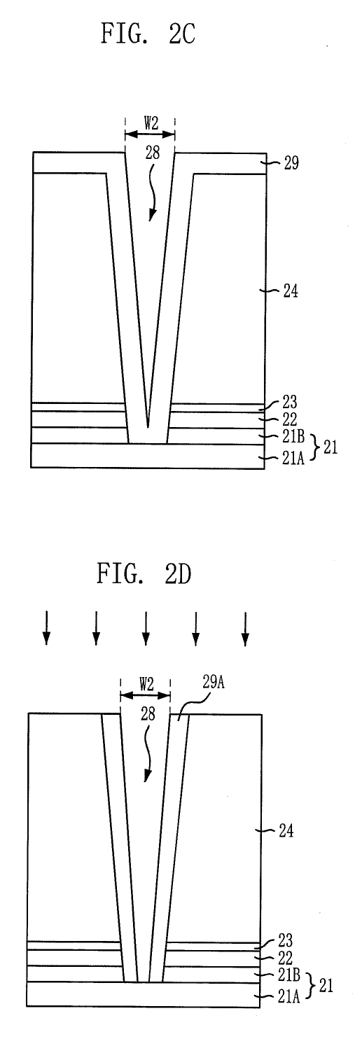

FIGS. 2A to 2D are cross-sectional views of a method for forming a contact in a semiconductor device in accordance with an embodiment of the present invention.

Referring to FIG. 2A, a bit line 21 including a bit line conductive layer 21A and a bit line hard mask layer 21B is formed over a substrate (not shown) including a certain lower structure.

Subsequently, a first insulation layer 22 is formed over the resultant structure including the bit line 21. An etch stop layer 23 and a second insulation layer 24 are formed over the first insulation layer 22. The second insulation layer 24 is formed to have a thickness enough to cover a capacitor (not shown) formed in a cell region in a semiconductor memory device.

After forming a hard mask layer 25 for a contact hole process over the second insulation layer 24, a photoresist pattern 27 having an opening to expose a targeted contact hole region is formed over the hard mask layer 25. Here, the opening of the photoresist pattern 27 exposes a targeted contact hole region to have a bigger CD than that defined by a design rule. Accordingly, even though the design rule decreases, a new photolithography apparatus does not need to be introduced. Furthermore, it is possible to secure a thickness of the photoresist pattern 27, and thus the hard mask layer 25 is easily etched. An anti-reflection layer 26 for preventing a reflection during the photo-exposure process may be formed under the photoresist pattern 27.

Then, the hard mask layer 25 is etched using the photoresist pattern 27 as an etch mask to form a hard mask pattern 25A.

Referring to FIG. 2B, the second insulation layer 24, the etch stop layer 23, the first insulation layer 22 and the bit line hard mask layer 21B are sequentially etched using the hard mask pattern 25A as an etch barrier to form a contact hole 28 until the bit line conductive layer 21A is exposed. A CD W1 of a top portion of the contact hole 28 corresponds to that of the opening of the photoresist pattern 27. Thus, the first CD W1 of the top portion of the contact hole 28 is greater than that defined by the design rule. Of course, the first CD W1 of the top portion of the contact hole 28 should have a selected value so that the contact hole 28 does not encroach on any adjacent contact hole.

Accordingly, in accordance with the present invention, a contact open failure is prevented because a contact margin increases even though the etch target, e.g., the second insulation layer 24, the etch stop layer 23, the first insulation layer 22, and the bit line hard mask layer 21B, is thick and the CD of the contact hole 28 decreases as it goes down from a top portion to a bottom portion. This means that a new advanced dry-etch apparatus is not necessary.

However, if the subsequent processes for forming a contact and an upper metal line are performed on the contact hole 28 as it has an increased CD at its top portion according to the process result in FIG. 2B, a bridge may be generated between the contact and its neighboring metal line. Therefore, to prevent such a bridge problem, additional processes shown in FIGS. 2C and 2D should be performed.

Referring to FIG. 2C, an insulation layer 29 for a spacer is formed over a surface of the resultant structure in FIG. 2B to decrease the first CD W1 of the top portion of the contact hole 28 until it reaches a second CD W2. The insulation layer 29 is formed until the second CD W2 of the top portion of the contact hole 28 reaches a CD as defined by the design rule, e.g., from approximately 100 Å to approximately 999 Å. The insulation layer 29, in this embodiment, may be an oxide layer, e.g., an O3-undoped silicate glass (USG) layer, a plasma enhanced tetraethyl ortho silicate (PETEOS) layer, a boron phosphosilicate glass (BPSG) layer, a phosphosilicate glass (PSG) layer, etc. The bottom portion of the contact hole 28 may be covered with the insulation layer 29.

Referring to FIG. 2D, the insulation layer 29 for a spacer in the bottom portion of the contact hole 28 is removed to expose the bit line conductive layer 21A, thereby leaving the insulation layer 29 on sidewalls of the contact hole 28 to form a spacer 29A while maintaining the second CD W2 of the top portion of the contact hole 28. The insulation layer 29 in the bottom portion of the contact hole 28 is removed by a blanket dry-etch process. During the blanket dry-etch process, a planarization process can be optionally performed in order to improve surface uniformity. The planarization process is preferably performed by using a touch chemical mechanical polishing (CMP) method, preferably with a polishing target ranging from approximately 500 Å to approximately 1,500 Å.

Although it is not shown, subsequent processes are performed to form a contact by filling a conductive material, e.g. metal, in the contact hole 28 having the second CD W2 and then to form a metal line connecting the contact over the second insulation layer 24.

In this embodiment, an example of the method for forming a contact between the bit line and the metal line has been described. However, the method can be applied to all kinds of semiconductor devices that require a deep contact structure. Particularly, this invention is preferably applied to a region having a low contact density because the CD of the top portion of the contact hole bigger than that defined by the design rule may cause neighboring contact holes to contact each other.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
providing a substrate;
forming an insulation layer over the substrate;
forming a photoresist pattern for a contact hole over the insulation layer, wherein the photoresist pattern includes an opening having a critical dimension (CD) greater than a desired contact CD;
forming a contact hole by selectively etching the insulation layer using the photoresist pattern; and
forming a spacer on a sidewall of the contact hole until a CD of the contact hole whose sidewall is covered by the spacer is reduced to a desired contact CD.

2. The method of claim 1, wherein the desired contact CD is a CD defined by a design rule for the semiconductor device.

3. The method of claim 1, wherein the substrate includes a bit line having a bit line conductive layer and a bit line hard mask layer sequentially formed under the insulation layer and forming the contact hole is performed to expose the bit line conductive layer by etching the insulation layer and the bit line hard mask layer.

4. The method of claim 1, further comprising forming a hard mask layer over the insulation layer before forming the photoresist patterns.

5. The method of claim 4, wherein forming the contact hole is performed using the hard mask layer patterned by the photoresist pattern.

6. The method of claim 1, wherein forming the spacer comprises:
forming an insulation layer for a spacer over a surface of a resultant structure including the contact hole; and
removing the insulation layer for the spacer in a bottom portion of the contact hole.

7. The method of claim 6, wherein the insulation layer for the spacer is made of an oxide-based layer.

8. The method of claim 7, wherein the insulation layer for the spacer includes an O3-undoped silicate glass (USG) layer, a plasma enhanced tetraethyl ortho silicate (PETEOS) layer, a boron phosphosilicate glass (BPSG) layer, a phosphosilicate glass (PSG) layer, or a combination thereof.

9. The method of claim 7, wherein a thickness of the insulation layer for the spacer ranges from approximately 100 Å to approximately 999 Å.

10. The method of claim 6, wherein removing the insulation layer for the spacer in the bottom portion of the contact hole is performed by a blanket dry-etch process.

11. The method of claim 7, wherein forming the spacer further includes performing a planarization process after removing the insulation layer for the spacer in the bottom portion of the contact hole.

12. The method of claim 6, wherein the planarization process is performed using a touch chemical mechanical polishing (CMP) method.

13. The method of claim 12, wherein the touch CMP method is performed with a polishing target ranging from approximately 500 Å to approximately 1,500 Å.

14. The method of claim 1, wherein the contact hole has a CD selected so that the contact hole does not encroach on any adjacent contact hole.

15. The method of claim 1, further comprising forming a contact by filling the contact hole with a conductive material after forming the spacer.
